(19) United States
(12) Patent Application Publication
(10) Pub. No.: US 2019/0280655 A1
(43) Pub. Date: Sep. 12, 2019

(54) AMPLIFIER CIRCUIT AND BUTTER AMPLIFIER

(71) Applicant: Raydium Semiconductor Corporation, Hsinchu (TW)

(72) Inventors: Chi-Hsiang OULEE, Taitung City (TW); Tzong-Yau KU, Hsinchu City (TW); Jun-Ren SHIH, Hsinchu City (TW)

(21) Appl. No.: 16/296,405

(22) Filed: Mar. 8, 2019

Related U.S. Application Data
(60) Provisional application No. 62/640,063, filed on Mar. 8, 2018.

(51) Int. Cl. H03F 1/34; H03F 3/45; H03F 3/68; G09G 3/36

(52) U.S. Cl. CPC H03F 1/342; H03F 3/45269; H03F 3/68; G09G 3/3688; H03F 2200/129; G09G 2310/0291; H03F 2203/45116; H03F 2203/45512; H03F 2203/45536; H03F 2200/153; H03F 2200/156

(57) ABSTRACT

An amplifier circuit and a buffer amplifier are provided. The amplifier circuit includes an operational amplifier stage, an output stage, a first compensation capacitor, and a first decoupling circuit. The operational amplifier stage is coupled between a first input terminal, a second input terminal, a first control node, and a second control node. The first compensation capacitor is coupled between the output terminal and the first control node. The first decoupling circuit has a first switch, a first current source and a first ground terminal. The first switch is coupled to the first control node, and the first current source is connected between the first switch and the first ground terminal. The decoupling circuit is used for providing a discharging path for the first coupling current of the first compensation capacitor.

### FIELD OF THE INVENTION

The present invention relates to an amplifier circuit and a buffer amplifier using the same. Specifically, the present invention relates to an amplifier circuit and a buffer amplifier using the same that have enhanced slew rate.

### BACKGROUND OF THE INVENTION

A conventional liquid crystal display has a source driver that outputs pixel data to the data lines of the display panel using buffers. Such buffer is usually formed of an operational amplifier wherein the output terminal coupled to the input terminal. A compensation capacitor is usually disposed between the input stage and the output stage of the operational amplifier so as to utilize the Miller effect to improve the stability of the operational amplifier.

In the prior art, a type of source driver is provided, wherein a ramp source driver provides ramp voltage, and a buffer outputs pixel signals corresponding to a plurality of data lines into the display panel at a time. In this type of source driver, the capacitance loading so high that the compensation capacitor has a high capacitance. However, a compensation capacitor having a high capacitance will generate a coupling current that enters into the feedback circuit of the operational amplifier, resulting in slow transfer rate of input signals into output signals.

For instance, when the source driver generates a ramp-up voltage, the operational amplifier generates a control signal that provides a negative voltage to the gate of the PMOS transistor so as to turn on the PMOS transistor. Nevertheless, a coupling current entering into the operational amplifier increases the voltage level imposed on the gate of the PMOS transistor and thus decreases the level to which the PMOS transistor turns on. Consequently, the output voltage has a slope smaller than that of the input voltage. One solution for the aforementioned problem is to increase the bias current of the operational amplifier stage so as to decrease influence of the coupling circuit on the transistors in the output stage. However, the solution increases the electricity consumption of the operational amplifier. In addition, the pole of the amplifier stage is moved lower in frequency, reducing the stability of the circuit.

Therefore, the buffer for source drivers in the prior art still have room for improvement.

### SUMMARY OF THE INVENTION

In light of the above, one of the objectives of the present invention is to provide an amplifier circuit and a buffer amplifier in which at least one decoupling circuit is used to offset the influence caused by the coupling current generated by the compensation capacitor, thereby increasing the slew rate of the amplifier circuit.

One embodiment of the present invention provides an amplifier circuit including an operational amplifier stage, an output stage, a first compensation capacitor and a first decoupling circuit. The operational amplifier stage is coupled between a first input terminal, a second input terminal, a first control node, and a second control node. The operational amplifier is used for receiving an input signal via the first input terminal and the second input terminal, and outputting a first control signal and a second control signal via the first control node and the second control node. The output stage is coupled between the first control node, the second control node, and an output terminal. The output terminal is used for receiving the first control signal and the second control signal, and outputting an output signal to the output terminal according to the first control signal and the second control signal. The first compensation capacitor is coupled between the output terminal and the first control node. The first decoupling circuit has a first switch, a first current source, and a first ground terminal. The first switch is coupled to the first control node. The first current source is connected between the first switch and the first ground terminal. The first decoupling circuit is used for providing a discharging path for a first coupling current of the first compensation capacitor.

Another embodiment of the present invention provides a buffer amplifier applicable to a ramp source driver of a display device. The buffer amplifier comprises the aforementioned amplifier circuit, wherein the output terminal is coupled to the second input terminal.

To further understand the features and technical content of the present invention, please refer to the following detailed descriptions and drawings related to the present invention. However, the provided drawings are used only for providing reference and descriptions, and are not intended to limit the present invention.

### BRIEF DESCRIPTION OF THE DRAWINGS

FIG. 1 shows the schematic view of an amplifier circuit according to a first embodiment of the present invention.

FIG. 2A shows the schematic view of the amplifier circuit of FIG. 1 in operation.

FIG. 2B shows the voltage-time diagram of an input signal of the amplifier circuit of FIG. 2A and the control signal received by the first switch.

FIG. 3 shows a schematic view of an amplifier circuit according to a second embodiment.

FIG. 4 shows a schematic view of the amplifier circuit of FIG. 3.

FIG. 5A shows the voltage-time diagram of the amplifier circuit of the second embodiment with the first switch and the second switch being opened when the amplifier circuit is receiving a ramp-up voltage.

FIG. 5B shows the voltage-time diagram of the amplifier circuit of the second embodiment with the first switch and the second switch being closed when the amplifier circuit is receiving a ramp-up voltage.

FIG. 6 shows a schematic view illustrating the amplifier circuit according to a third embodiment of the present invention.

FIG. 7A shows the schematic view of the amplifier circuit of FIG. 6 in operation.

FIG. 7B shows the voltage-time diagram of an input signal of the amplifier circuit of FIG. 7A and the control signal received by the first switch.

FIG. 8 is a schematic view illustrating a buffer amplifier according to a fourth embodiment of the present invention.

### DETAILED DESCRIPTION OF THE PREFERRED EMBODIMENTS

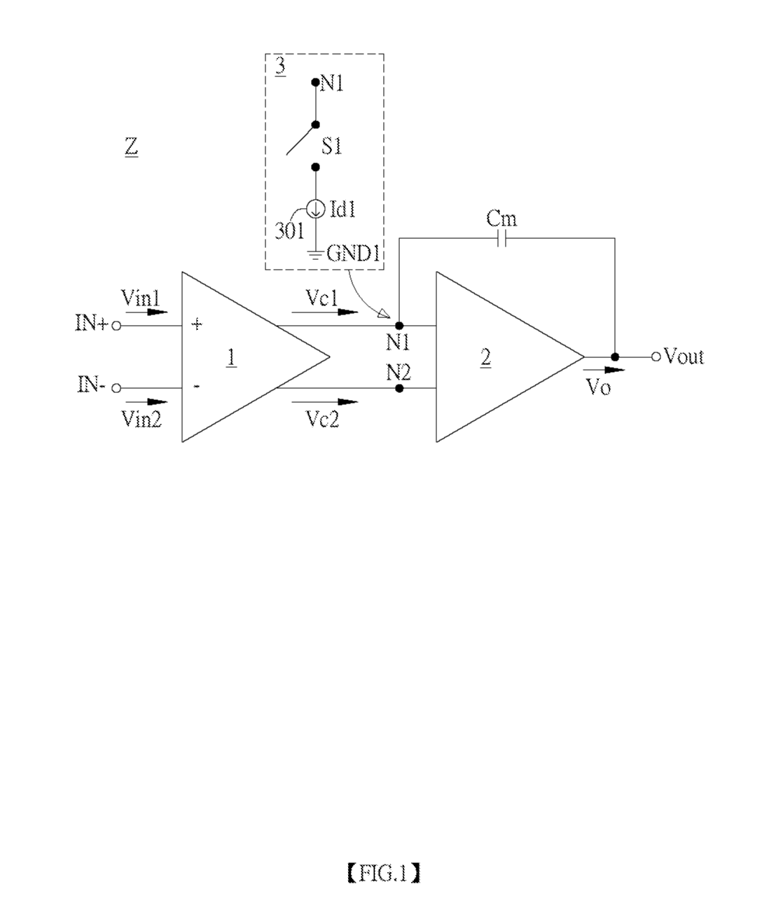

Embodiments of the present invention are described below with reference to FIG. 1 to FIG. 8. A person skilled in the art can understand the advantages and effects of the present invention from the description disclosed below. However, the content disclosed below is not intended to limit the protection scope of the present invention. The present invention can be implemented by a person skilled in the art based on different perspectives and applications without departing from the concept and spirit of the present invention. In addition, it should be stated in advance that the accompanying drawings of the present invention are merely used for illustration, and are not drawn according to actual dimensions for sake of clear illustration. Moreover, the same reference number corresponds to the same component. It should also be understood that expressions such as one component is “connected to” or “disposed on” another may mean that the former is either directly or indirectly connected to or disposed on the latter, wherein “connected” may refer to either physical or electrical connection.

### First Embodiment

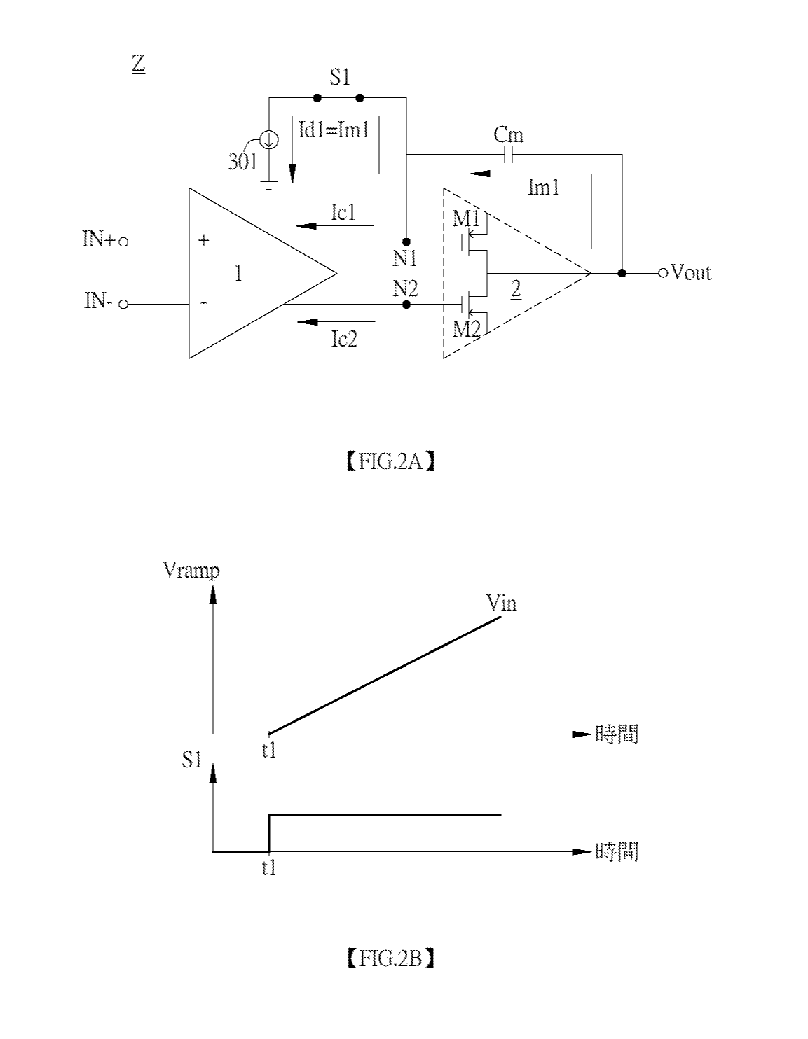

The first embodiment of the present invention is described below with reference to FIG. 1 to FIG. 2B. The first embodiment of the present invention provides an amplified circuit Z having an operational amplifier stage 1, an output stage 2, a first compensation capacitor Cm and a first decoupling circuit 3. The operational amplifier stage 1 is coupled between the first input terminal IN+, the second input terminal IN−, the first control node N1, and the second control node N2. As shown in FIG. 1, the operational amplifier stage 1 receives a first input signal Vin1 and a second input signal Vin2 via the first input terminal IN+ and the second input terminal IN−, and outputs a first control signal Vc1 to the first control node N1, and outputs a second control signal Vc2 to the second control node N2. Specifically, in practice, the operational amplifier stage 1 can include an input stage and at least one gain stage, wherein the input stage is used for input the difference between the first input signal Vin1 and the second input signal Vin2 to the gain stage as an input signal thereof. The gain stage is used for amplifying the input signal. However, the present invention is not limited thereto.

Referring to FIG. 1, the output stage 2 is coupled to the first control node N1, the second control node N2, and the output terminal Vout. The output stage 2 receives the first control signal Vc1 and the second control current Vc2 and outputs the output signal Vo according to the first control signal Vc1 and the second control signal Vc2. For example, the output stage 2 can include a PMOS transistor and an NMOS transistor connected in series. The PMOS transistor is coupled to the first control node N1 with the gate thereof so as to receive the first control signal Vc1, and the NMOS transistor M2 is coupled to the second control node N2 with the gate thereof so as to receive the second control signal Vc2. The PMOS transistor and the NMOS transistor M2 are both coupled to the output terminal Vout using the drain thereof. The PMOS transistor is coupled to a positive source terminal and the NMOS transistor is coupled to a negative source terminal with the source thereof. The output stage outputs the output signal Vo to the output terminal Vout according to the turn on state of the PMOS transistor and that of the NMOS transistor. However, the present invention is not limited thereto. A person skilled in the art can design the circuit structure of the output stage 2 according to actual needs.

As shown in FIG. 1, the amplified circuit Z has a first compensation capacitor Cm and a first decoupling circuit 3. The first compensation capacitor Cm is coupled between the first control node N1 and the output terminal Vout. Specifically, in the present embodiment, the first compensation capacitor Cm provides the Miller Effect, wherein the capacitance of the amplifier circuit Z is amplified, and the stability of the amplified circuit Z is improved. The first decoupling circuit 3 includes the first switch S1, the first current source 301 and the first ground terminal GND1. The first switch S1 is coupled to the first control node N1. The first current source 301 is connected between the first switch S1 and the first ground terminal GND1. More specifically, the node N1 in the first decoupling circuit 3 shown in FIG. 1 is to be coupled to the first control node N1 in a manner such that the circuit shown in FIG. 2A is formed. The first current source 301 can be a current mirror. However, the present invention is not limited thereto. In the present embodiment, the first current source 301 is used for providing a first decoupling current Id1 so that first decoupling circuit 3 forms a path for discharging the first compensation capacitor Cm. The detail regarding the amplified circuit Z will be described below.

The schematic view illustrating the amplified circuit Z of the first embodiment will be described with reference to FIG. 2A and FIG. 2B below. For the sake of brief illustration, the first input signal Vin1, the second input signal Vin2, the first control signal Vc1, the second control signal Vc2 and the output signal Vo are omitted in FIG. 2A. In addition, in FIG. 2A, the output stage 2 includes a PMOS transistor M1 and an NMOS transistor M2 connected in series, wherein the example of the operation mode of thereof has already been described above, and will not be further described herein.

With reference to FIG. 2A and FIG. 2B, in which FIG. 2B shows the voltage-time diagram of an input signal Vin of the amplifier circuit Z in FIG. 2A and the control signal received by the first switch S1. In the present embodiment, when the input voltage is a ramp-up voltage Vramp, since the PMOS transistor M1 turns on when receiving a negative voltage, the first control signal Vc1 is exemplified as a first control current Ic1 flowing from the first control node N1 to the operational amplifier stage 1 so as to turn on the PMOS transistor M1. Under this condition, the first compensation capacitor Cm generates a coupling current Im1 flowing into the first control node N1. The first coupling current Im1 will cause the increase in voltage level in the first control N1, decreasing the level to which the PMOS transistor M1 turns on. Therefore, in the present embodiment, the first decoupling circuit 3 to be coupled to the first control node N1 is provided, in which the first switch S1 is closed at the start of the ramp-up voltage Vramp, upon which the first current source 301 provides a first decoupling current Id1 flowing to the first ground terminal GND1. More specifically, in the present embodiment, the first decoupling current Id1 is equal to the first coupling current Im1 such that the first coupling current Im1 that would have flowed to the first control node N1 is directed to flow into the first decoupling circuit 3, in which the first coupling current Im1 flows into the first ground terminal GND1. In this way, the first decoupling circuit 3 provides the discharging path for the first coupling current Im1 of the first compensation capacitor Cm.

Through the aforementioned technical solution, the net current flowing through the first control node N1 is the first control current Ic1, thereby alleviating the influence of the first coupling current Im1 on the slewing process when the amplified circuit Z is outputting signals. That is to say, in the present embodiment, the problem of output signals not being in sync and in proportion to the input signals caused by the Miller effect can be solved with the first decoupling circuit 3. Moreover, in contrast to the technical solution of prior art in response to the Miller effect, the present embodiment dispenses with increased control currents (Ic1, Ic2) and thus high electricity consumption, thereby avoiding decreased stability of the amplified circuit Z caused by increased control currents (Ic1, Ic2).

More specifically, the first coupling current Im1 can be derived from the slope of the ramp-up voltage dV/dT and the capacitance of the first compensation capacitor Cm as shown below:

Im1=(dV/dT)*Cm

After the first coupling current Im1 is derived, the first decoupling current Id1 is set to be equal to the first coupling current Im1 so that the first coupling current Im1 generated from the first compensation capacitor Cm can flow into the first ground terminal GND1 instead of the operational amplifier stage 1 and thus is prevented from affecting the level to which the PMOS transistor M1 is turned on.

Moreover, in the present embodiment, the first switch S1 can set to be closed only when the input signal (Vin1−Vin2) is a ramp-up voltage. That is, the first switch S1 is opened when the input signal (Vin1−Vin2) is not a ramp-up voltage. In addition, the first switch S1 can be opened or closed through a control signal; however, the present invention is not limited thereto either.

### Second Embodiment

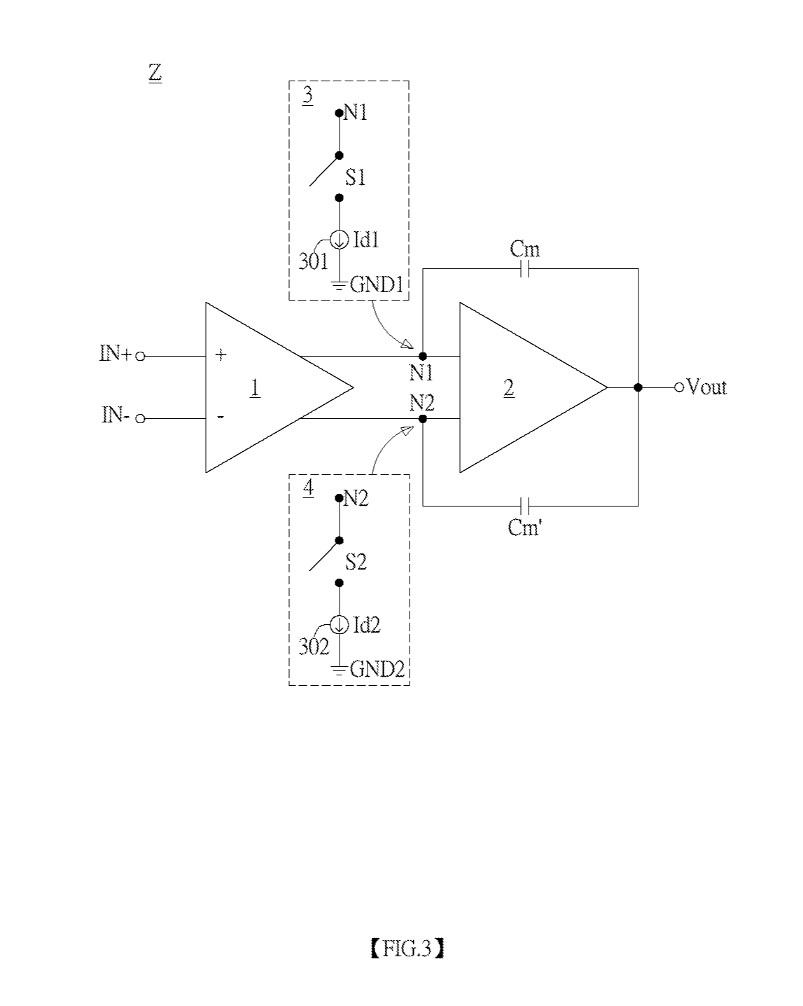

With reference to FIG. 3, the main difference between the amplified circuit Z of the second embodiment and that of the first embodiment is: the amplified circuit Z of the present embodiment further includes a second compensation capacitor Cm′ and a second decoupling circuit 4. The second decoupling circuit 4 has a second switch S2, a second current source 302 and a second ground terminal GND2. The second switch S2 is coupled to the second control node N2. The second current source 302 is connected between the second switch S2 and the second ground terminal GND2.

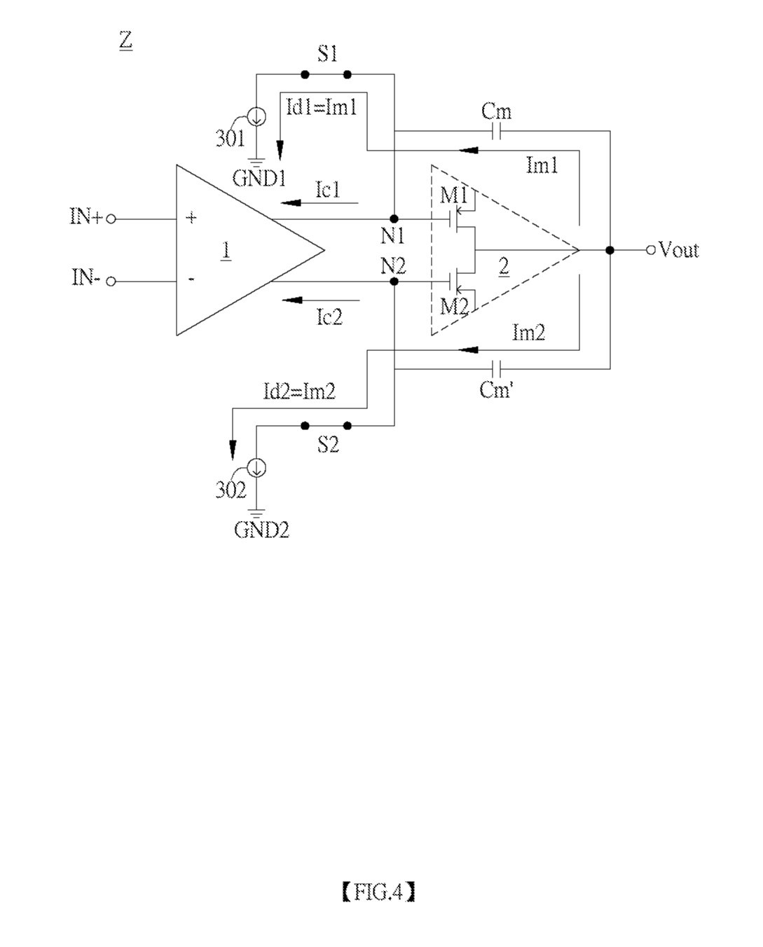

FIG. 4 shows a schematic view of the amplifier circuit of FIG. 3. To be specific, the input signal of the present embodiment is a ramp-up voltage. Therefore, the direction of the first control current Ic1 and the second control current Ic2 in the present embodiment is the same of that of the first control current Ic1 and the second control current Ic2 in FIG. 2A. As stated above, the first compensation capacitor Cm generates a first coupling current Im1 flowing towards the first control node N1. Since the amplified circuit Z of the present embodiment has symmetry, the second compensation capacitor Cm′ also generates a second coupling current Im2 flowing towards the second control node N2. In this embodiment, outputting a ramp-up voltage requires the PMOS transistor M1 to be turned on and the NMOS transistor M2 to be turned off. However, the second coupling current Im2 flowing towards the second control node N2 can decrease the level to which the NMOS transistor M2 is turned off. Therefore, in the present embodiment, the amplified circuit Z has the second decoupling circuit 4, in which the second current source 302 enables a second decoupling current Id2 to flow through. The second decoupling current Id2 is equal to second coupling current Im2, and the second switch S2 is closed when the input signal is a ramp-up voltage. In this way, the second coupling current Im2 will not flow into the second control node N2; rather, the second coupling current Im2 will flow into the second ground terminal GND2. In other words, the second decoupling circuit 4 provides a discharging path for the second coupling current Im2 of the second compensation capacitor Cm′. Through the abovementioned technical solution, the present embodiment can achieve an enhanced slewing process. On the other hand, by way of the technical solution of the present embodiment, the stability provided by the first compensation capacitor Cm and second compensation capacitor Cm′ is kept, and at the same time the disadvantages of the first compensation capacitor Cm and the second compensation capacitor Cm′, that is, the decreased slew rate caused by the coupling currents can be prevented.

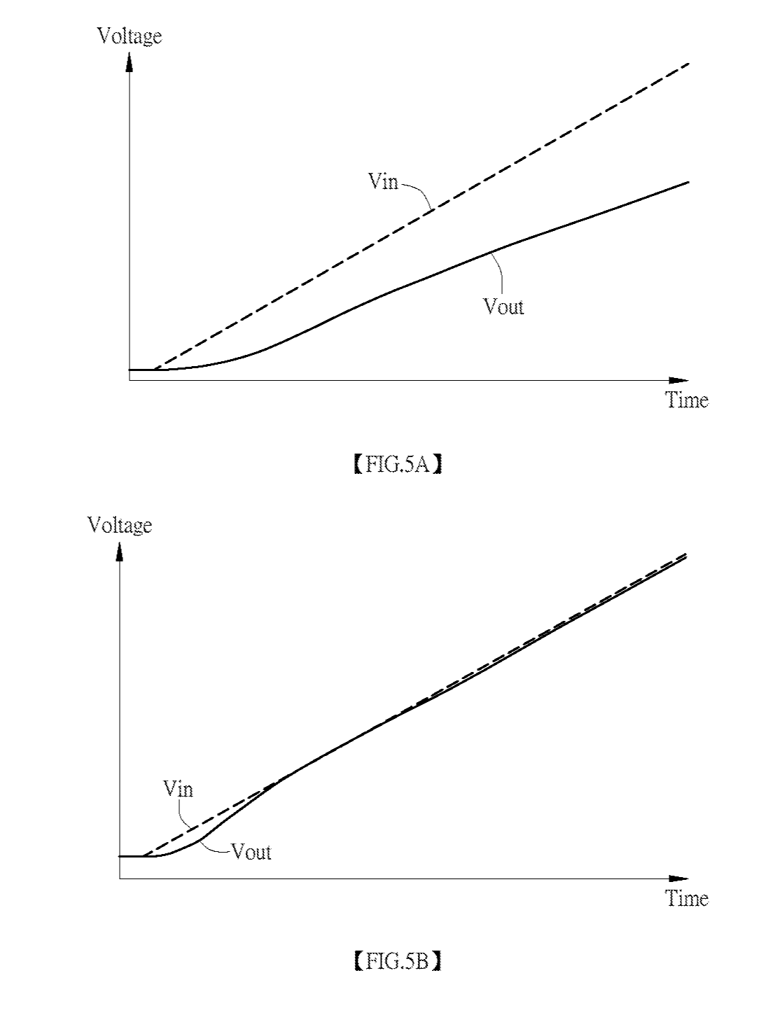

With reference to FIG. 5A and FIG. 5B, wherein FIG. 5A shows the voltage-time diagram of the amplifier circuit of the second embodiment with the first switch S1 and the second switch S2 being opened when the amplifier circuit is receiving a ramp-up voltage, and FIG. 5B shows the voltage-time diagram of the amplifier circuit of the second embodiment with the first switch and the second switch being closed when the amplifier circuit is receiving a ramp-up voltage. As shown in the figure, when the ramp-up voltage is inputted, if the first switch S1 and the second switch S2 are opened, the output signal of the amplified circuit Z is not in proportion to the input signal, and if the first switch S1 and the second switch S2 are closed, the output signal Vout is essentially in proportion to the input signal. One can derived from FIG. 5A and FIG. 5B that the first decoupling circuit 3 and the second decoupling circuit 4 can effectively reduce the influence of the coupling currents generated by the first compensation capacitor Cm and the second compensation capacitor Cm′ on the amplified circuit Z.

### Third Embodiment

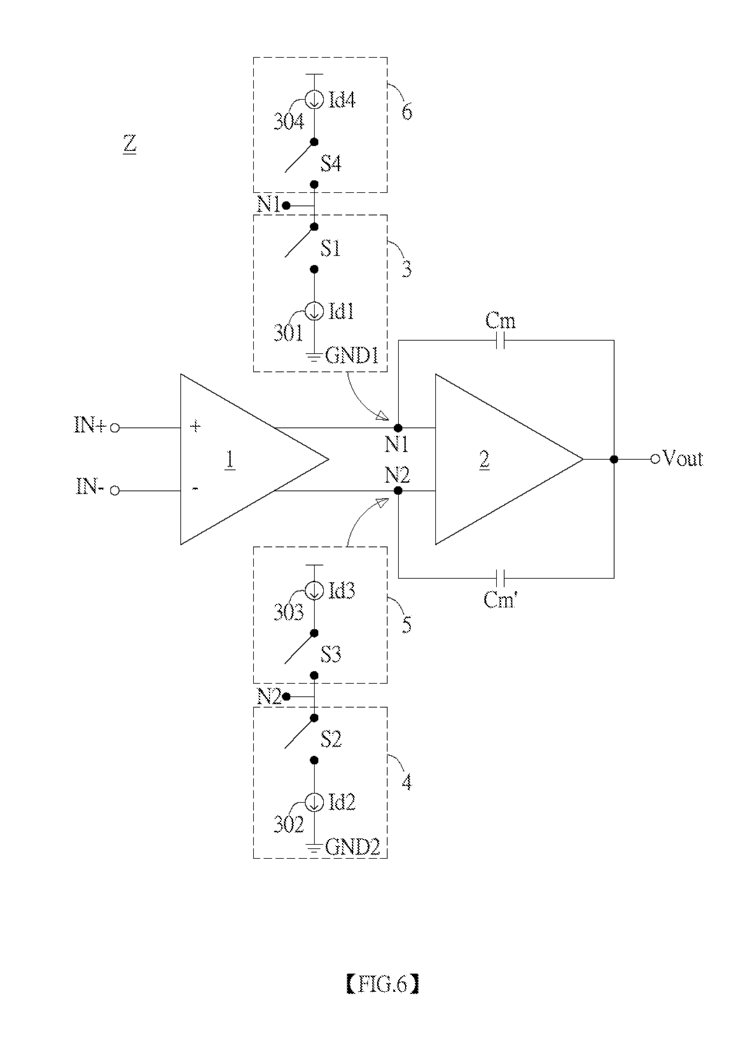

With reference to FIG. 6, the difference between the third embodiment and the abovementioned embodiments is: the present embodiment further includes a third decoupling circuit 5 and a fourth decoupling circuit 6. The third decoupling circuit 5 has a third switch S3 and a third current source 303. The fourth decoupling circuit 6 has a fourth switch S4 and a fourth current source 304. As shown in FIG. 6, the third current source 303 provides a third decoupling current Id3, and the third switch S3 is coupled to the second control node N2; the fourth current source 304 provides a fourth decoupling current Id4, and the fourth switch S4 is coupled to the first control node N1. The third current source 303 and the fourth current source 304 are used for providing a source of the coupling current of the first compensation capacitor Cm and the second compensation capacitor Cm′.

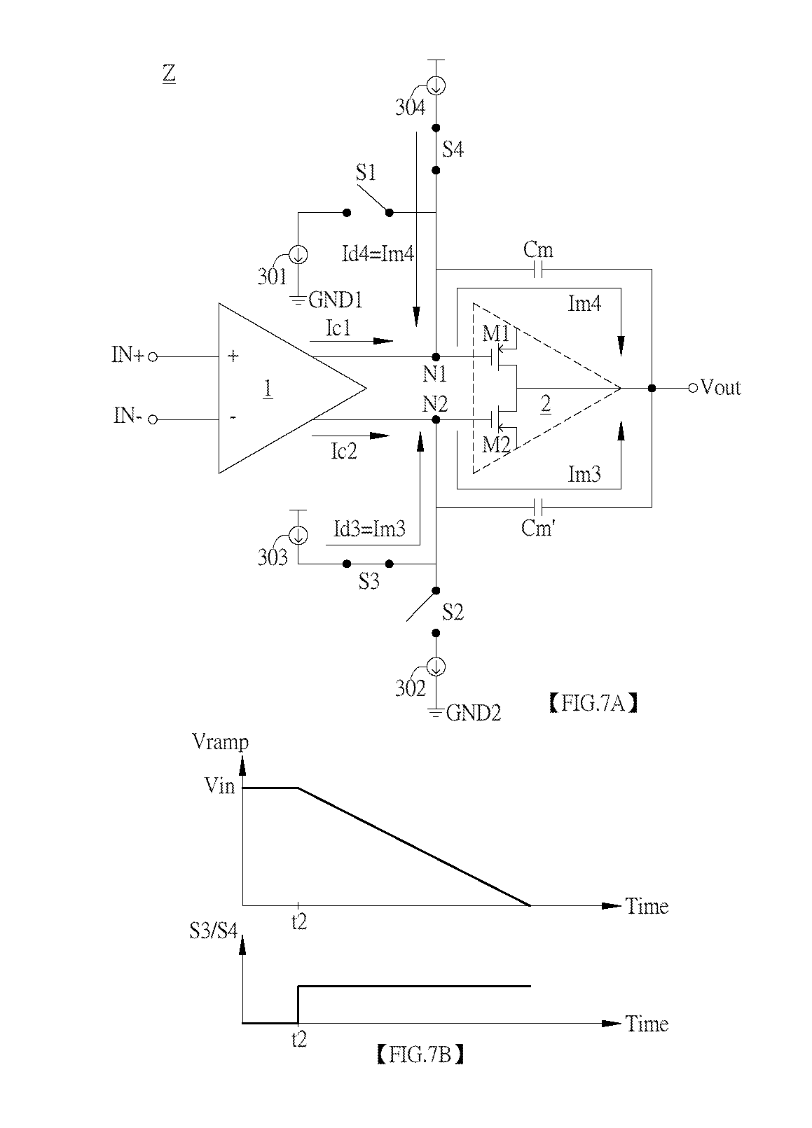

Specifically, please refer to FIG. 7A and FIG. 7B, in which FIG. 7A shows the schematic view of the amplifier circuit of FIG. 6 in operation, and FIG. 7B shows the voltage-time diagram of an input signal of the amplifier circuit of FIG. 7A and the control signal received by the first switch. When an input signal Vin is inputted into the amplified circuit Z at time point t2, wherein the input signal Vin is a ramp-down voltage as shown in FIG. 7B, the amplified circuit Z of FIG. 7A requires the NMOS transistor M2 to turn on and the PMOS transistor M1 to turn off. In this condition, the first control current Ic1 flows towards the first control node N1 so as to turn the PMOS transistor M1 off; the second control current Ic2 flows towards the second control node N2 so as to turn the NMOS transistor M2 on. However, the first compensation capacitor Cm and the second compensation capacitor Cm′ of the present embodiment generate a fourth coupling current Im4 and a third coupling current Im3 to the output terminal Vout respectively. The third coupling current Im3 will decrease the level to which the NMOS transistor M2 is turned on, while the fourth coupling current Im4 will cause the PMOS transistor M1 to be turned on.

Therefore, in the present embodiment, the amplified circuit Z further includes a third decoupling circuit 5 coupled to the second control node N2, in which the third switch S3 is closed when the amplified circuit Z receives a ramp-down voltage at time point t2 such that the third decoupling current Id3 flows into the second control node N2, thereby compensating for the decrease in voltage level in the second control node N2 caused by the third coupling current Im3 flowing towards the output stage 2. In other words, the third decoupling circuit 5 is used for providing the source of the third coupling current Im3 generated by the second compensation capacitor Cm′. On the other hand, the decrease in voltage level in the first control node N1 caused by the fourth coupling current Im4 may turn the PMOS transistor M1 on; therefore, the present embodiment further includes the fourth decoupling circuit 6 coupled to the first control node N1, in which the fourth switch S4 is closed so that the fourth decoupling current Id4 flows into the first control node N1 so as to compensating for the decrease in voltage level in the first control node N1 caused by the fourth coupling current Im4 flowing towards the output terminal Vout. That is to say, the fourth decoupling circuit 6 is used for providing the source of the fourth coupling current Im4 generated by the first compensation capacitor Cm.

It can be understood that, in the present embodiment, the third switch S3 and the fourth switch S4 can be set to close to from a conductive path when the input signal is a ramp-down voltage. When the input signal is not a ramp-down voltage, the input signal is opened so as to avoid extra electricity consumption of the amplified circuit Z.

### Fourth Embodiment

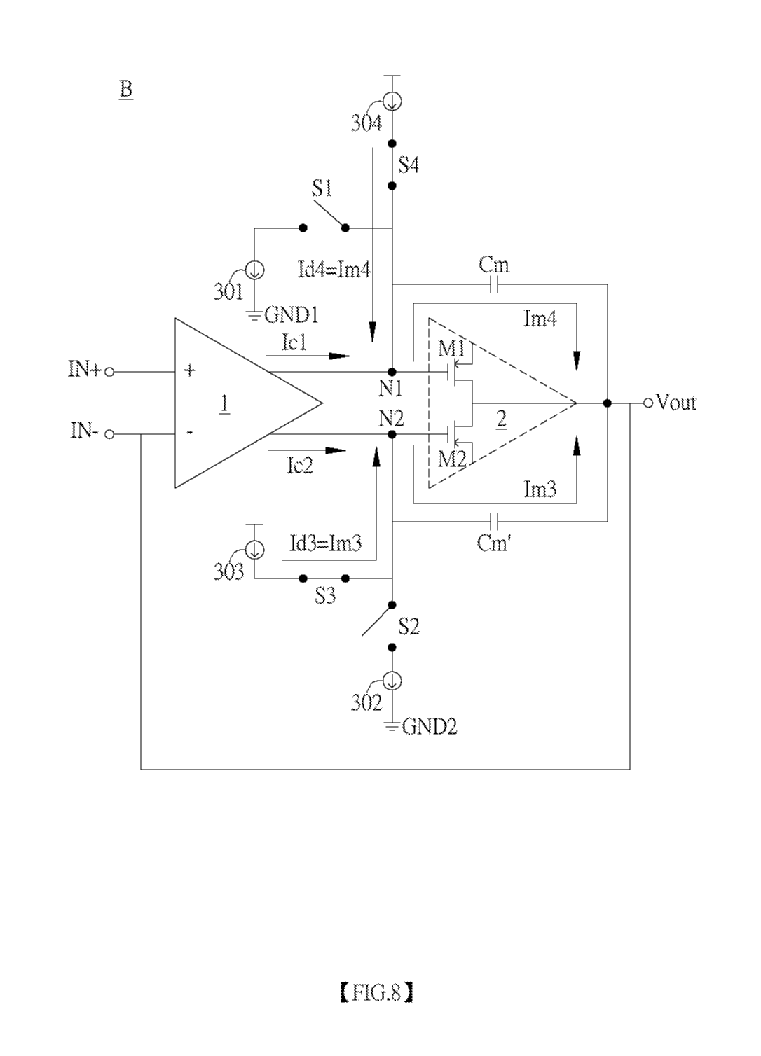

Referring to FIG. 8, the fourth embodiment of the present invention provides a buffer amplifier B using the amplified circuit Z according to either one of the abovementioned amplified circuit Z, wherein the output stage 2 is coupled to the second input terminal IN−. When the buffer amplifier B of the present embodiment is applied to a ramp source driver of a display device, the negative influence of the coupling currents generated by the first compensation capacitor Cm and the second compensation capacitor Cm′ can be reduced. Therefore, the buffer amplifier B can on the one hand improve the stability with the first compensation capacitor Cm and the second compensation capacitor Cm′, and on the other hand provide an output signal of high accuracy compared to the buffer of prior art.

In summary, the amplifier circuit and the buffer amplifier provided by the embodiments of the present invention can achieve “the first decoupling circuit provides a discharging path for the first coupling current generated by the first compensation capacitor when the first switch is closed” through the technical solution of “the first decoupling circuit has the first switch, the first current source, and the first ground terminal, the first switch being coupled to the first control node, and the first current source being connected between the first switch and the first ground terminal.”

The present invention has been described with reference to the above embodiments, but the above embodiments are merely examples for implementing the present invention. It should be noted that the disclosed embodiments are not intended to limit the scope of the present invention. On the contrary, any modification and equivalent configuration within the spirit and scope of the appended claims shall fall within the scope of the present invention.

What is claimed is:

1. An amplifier circuit, comprising:
an operational amplifier stage coupled between a first input terminal, a second input terminal, a first control node, and a second control node, the operational amplifier being used for receiving an input signal via the first input terminal and the second input terminal, and outputting a first control signal and a second control signal via the first control node and the second control node;
an output stage coupled between the first control node, the second control node, and an output terminal, the output terminal being used for receiving the first control signal and the second control signal, and outputting an output signal to the output terminal according to the first control signal and the second control signal; and
a first compensation capacitor coupled between the output terminal and the first control node; and
a first decoupling circuit having a first switch, a first current source, and a first ground terminal, the first switch being coupled to the first control node, the first current source being connected between the first switch and the first ground terminal,
wherein the first decoupling circuit is used for providing a discharging path for a first coupling current of the first compensation capacitor.

2. The amplifier circuit according to claim 1, wherein the first switch is closed to form a conductive path when the input signal is a ramp voltage.

3. The amplifier circuit according to claim 1, wherein the output stage includes a PMOS transistor and an NMOS transistor, in which a gate of the PMOS transistor is coupled to the first control node, a gate of the NMOS transistor is coupled to the second control node, a drain of the PMOS transistor and a drain of the NMOS transistor are coupled to the output terminal, and wherein the input signal includes a ramp-up period during which the first compensation capacitor outputs the first coupling current to the first control node, and the first current source enables a first decoupling current to flow from the first control node to the first ground terminal via the first current source.

4. The amplifier circuit according to claim 1, wherein the first decoupling current is equal to the first coupling current

5. The amplifier circuit according to claim 1, further comprising:
a second compensation capacitor coupled between the output terminal and the second control node; and
a second decoupling circuit having a second switch, a second current source, and a second ground terminal, the second switch being coupled to the second control node, and the second current source being connected between the second switch and the second ground terminal,
wherein the second decoupling circuit is used for providing a discharging path for a second coupling current of the second compensation capacitor.

6. The amplifier circuit according to claim 5, wherein the second switch is closed to form a conductive path when the input signal is a ramp voltage.

7. The amplifier circuit according to claim 5, wherein the output stage includes a PMOS transistor and an NMOS transistor, in which a gate of the PMOS transistor is coupled to the first control node, a gate of the NMOS transistor is coupled to the second control node, a drain of the PMOS transistor and a drain of the NMOS transistor are coupled to the output terminal, and wherein the output signal includes a ramp-up period during which the second compensation capacitor outputs the second coupling current to the second control node, and the second current source enables a second decoupling current to flow from the second control node to the second ground terminal via the second current source.

8. The amplifier circuit according to claim 5, further comprising a third decoupling circuit having a third switch and a third current source, the third switch being coupled between the second control node and the third current source, wherein the third decoupling circuit is used for providing a source of a third coupling current of the second compensation capacitor.

9. The amplifier circuit according to claim 8, wherein the third switch is closed to form a conductive path when the input signal is a ramp voltage.

10. The amplifier circuit according to claim 8, wherein the output stage includes a PMOS transistor and an NMOS transistor, in which a gate of the PMOS transistor is coupled to the first control node, a gate of the NMOS transistor is coupled to the second control node, a drain of the PMOS transistor and a drain of the NMOS transistor are coupled to the output terminal, and wherein the output signal includes a ramp-down period during which the second compensation capacitor outputs the third coupling current to the output terminal, and the third current source outputs a third decoupling current to the second control node.

11. The amplifier circuit according to claim 10, wherein the third coupling current is equal to the third decoupling current.

12. The amplifier circuit according to claim 1, further comprising a fourth decoupling circuit having a fourth switch and a fourth current source, the fourth switch being coupled between the first control node and the fourth current source, wherein the fourth decoupling circuit is used for providing a source of a fourth coupling current of the first compensation capacitor.

13. The amplifier circuit according to claim 12, wherein the fourth switch is closed to form a conductive path when the input signal is a ramp-down voltage.

14. The amplifier circuit according to claim 12, wherein the output stage includes a PMOS transistor and an NMOS transistor, in which a gate of the PMOS transistor is coupled to the first control node, a gate of the NMOS transistor is coupled to the second control node, a drain of the PMOS transistor and a drain of the NMOS transistor are coupled to the output terminal, and wherein the input signal includes a ramp-down period during which the first compensation capacitor outputs the fourth coupling current to the output terminal, and the fourth current source outputs a fourth decoupling current to the first control node.

15. The amplifier circuit according to claim 14, wherein the fourth coupling current is equal to the fourth decoupling current.

16. A buffer amplifier applicable to a ramp source driver of a display device,
the buffer amplifier comprising:
the amplifier circuit according to claim 1, wherein the output terminal is coupled to the second input terminal.
